(19) United States
(12) Patent Application Publication
(10) Pub. No.: US 2014/0293519 A1
(43) Pub. Date: Oct. 2, 2014

(54) ELECTRONIC DEVICE

(71) Applicant: Acer Incorporated, New Taipei City (TW)

(72) Inventor: Cheng-Pang Wang, New Taipei City (TW)

(73) Assignee: Acer Incorporated, New Taipei City (TW)

(21) Appl. No.: 14/185,119

(22) Filed: Feb. 20, 2014

(30) Foreign Application Priority Data
Apr. 2, 2013 (TW) 102111833

(51) Int. Cl. H05K 5/02; H05K 5/00

(52) U.S. Cl. CPC H05K 5/0226; H05K 5/0017
USPC 361/679.01

(57) ABSTRACT

An electronic device is provided, including a main body, a display module, a rotary member, a slider, a first hinge, and a second hinge. The display module has a recess and a first surface. The main body, the display module, and the rotary member are pivotally connected by the first hinge. The rotary member and the slider are pivotally connected by the second hinge. When the display module is in a closed position relative to the main body, the slider is accommodated in the recess. When the display module rotates relative to the main body from the closed position to an open position, the display module pushes the slider to rotate relative to the rotary member, and the rotary member rotates relative to the display module, such that the slider protrudes from the first surface.

### CROSS REFERENCE TO RELATED APPLICATIONS

The present application is based on, and claims priority from, Taiwan Patent Application No. 102111833, filed on Apr. 2, 2013, the disclosure of which is hereby incorporated by reference herein in its entirety.

### BACKGROUND OF THE INVENTION

1. Field of the Invention

The application relates in general to an electronic device, and in particular, to an electronic device with a rotary display module.

2. Description of the Related Art

Referring to FIG. 5, a conventional portable computer usually has a hinge H embedded in the rear side of the main body M for reducing thickness and weight of the portable computer, rather than the top side thereof. Though the thickness of the portable computer can be reduced, the rear side of the portable computer can be occupied by the hinge H and the display module D. Thus, heat dissipation holes and power sockets cannot be disposed on the rear side of the main body M.

### BRIEF SUMMARY OF INVENTION

An embodiment of the invention provides an electronic device, comprising a main body, a display module, a rotary member, a slider, a first hinge, and a second hinge. The display module has a recess and a first surface. The main body, the display module, and the rotary member are pivotally connected by the first hinge. The rotary member and the slider are pivotally connected by the second hinge. When the display module is in a closed position relative to the main body, the slider is accommodated in the recess. When the display module rotates relative to the main body from the closed position to an open position, the display module pushes the slider to rotate relative to the rotary member, and the rotary member rotates relative to the display module, such that the slider protrudes from the first surface.

In some embodiments, the main body includes a depression with the first hinge disposed therein.

In some embodiments, the display module has a display surface, a first surface, and a first inclined surface. The display surface and the first surface are disposed on opposite sides of the display module. The slider has a second surface and a second inclined surface. When the display module is in a closed position relative to the main body, the first surface is aligned with the second surface, and the first inclined surface is close to the second inclined surface.

In some embodiments, the electronic device further comprises a first torsion spring with the first hinge disposed therein, and the first torsion spring connects to the main body and the rotary member.

In some embodiments, the electronic device further comprises a second torsion spring with the second hinge disposed therein, and the second torsion spring connects to the rotary member and the slider.

In some embodiments, the electronic device further comprises a gear mechanism connecting the display module with the rotary member. When the display module rotates relative to the main body from the closed position to the open position, the rotary member is rotated relative to the display module by the gear mechanism.

In some embodiments, when the display module rotates relative to the main body from the closed position to the open position, the display module pushes the slider to rotate relative to the rotary member (a first direction), and the rotary member rotates toward the display module (a second direction). The first direction is opposite to the second direction.

In some embodiments, when the display module rotates relative to the main body from the closed position to the open position, the second hinge is situated in the recess.

### BRIEF DESCRIPTION OF DRAWINGS

The invention can be more fully understood by reading the subsequent detailed description and examples with references made to the accompanying drawings, wherein:

FIG. 14A is a perspective diagram of an electronic device according to an embodiment of the invention;

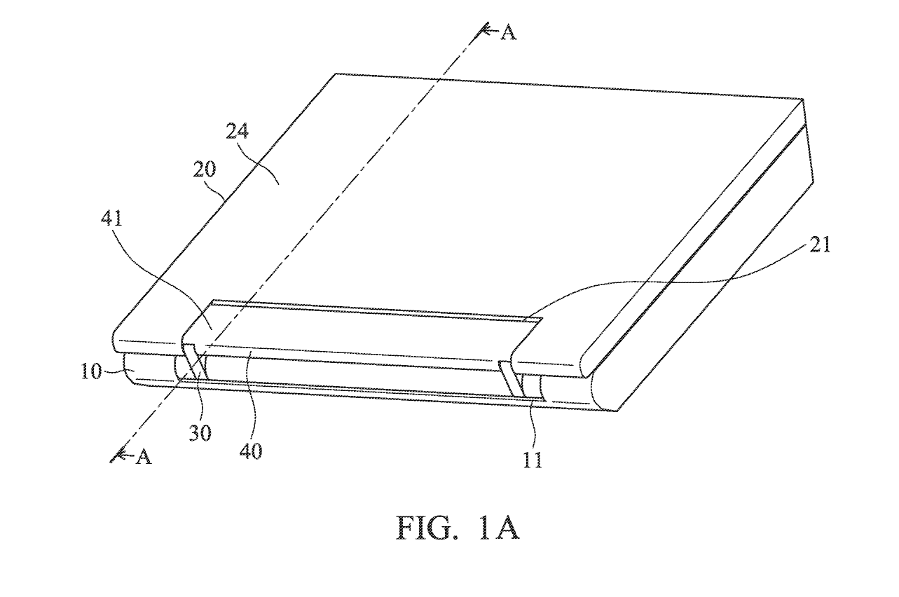

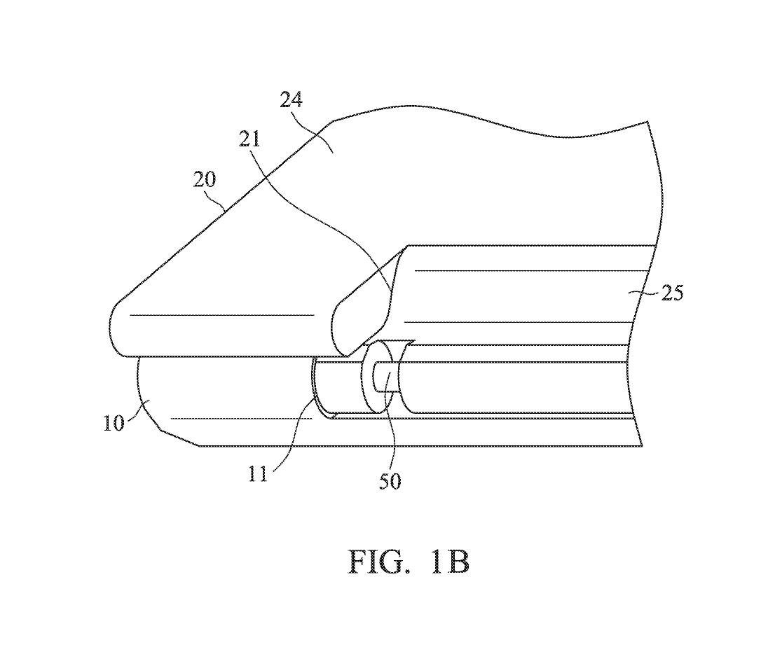

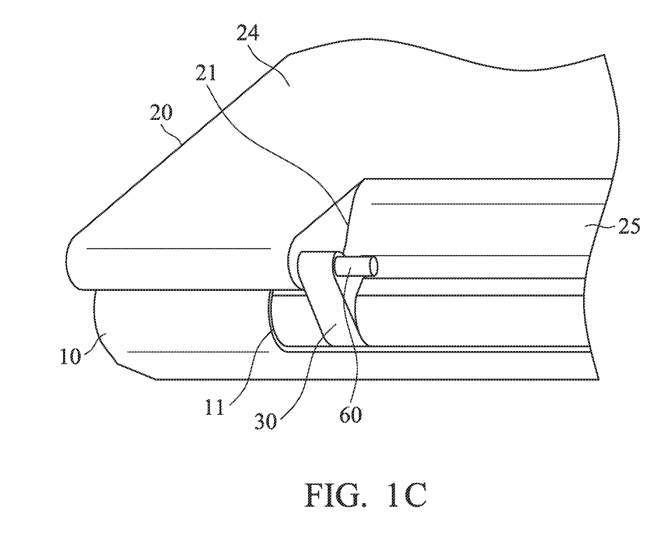

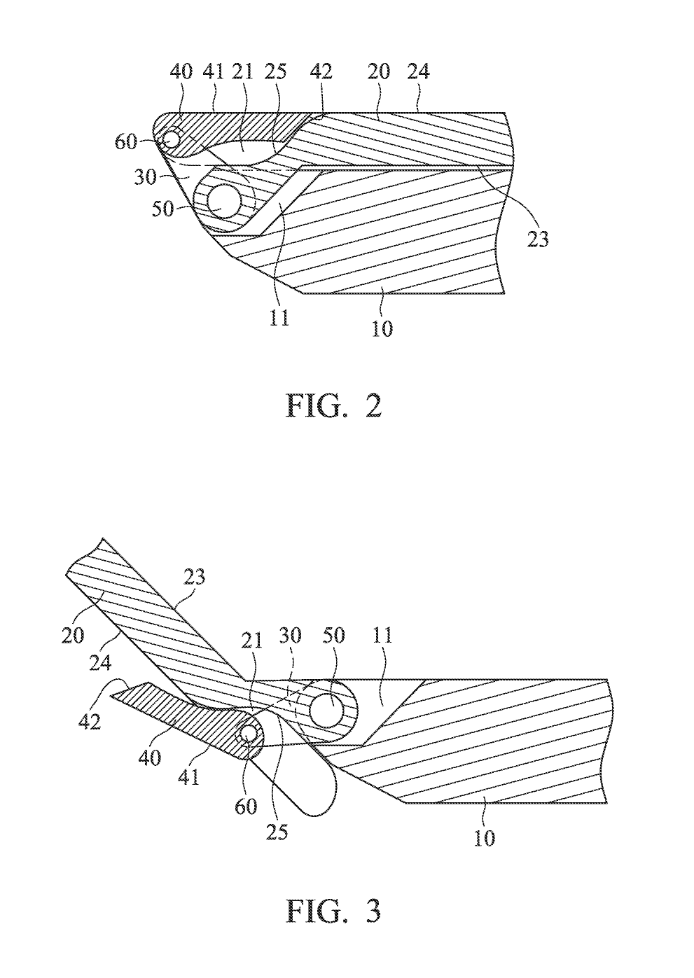

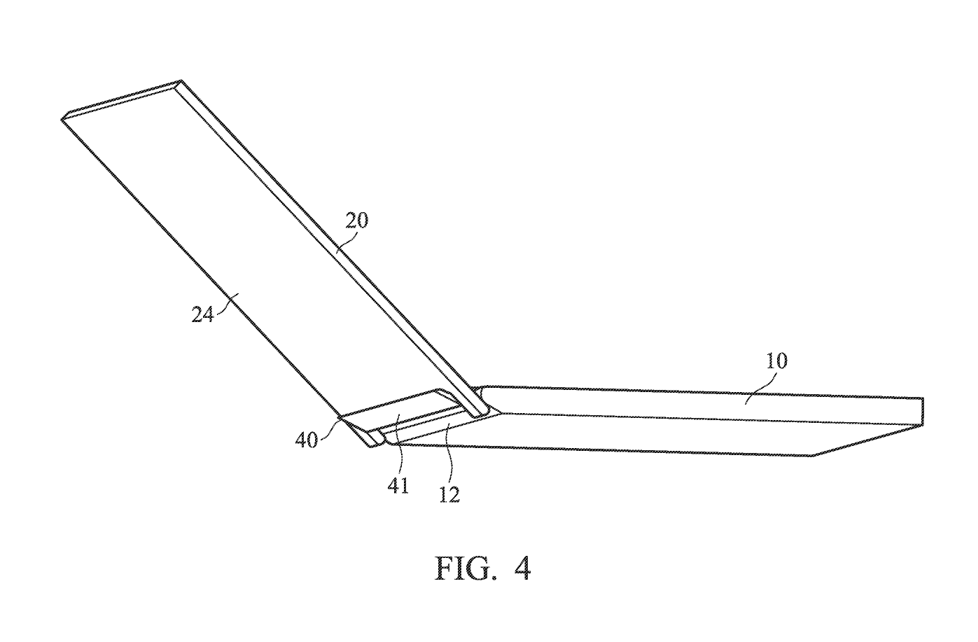

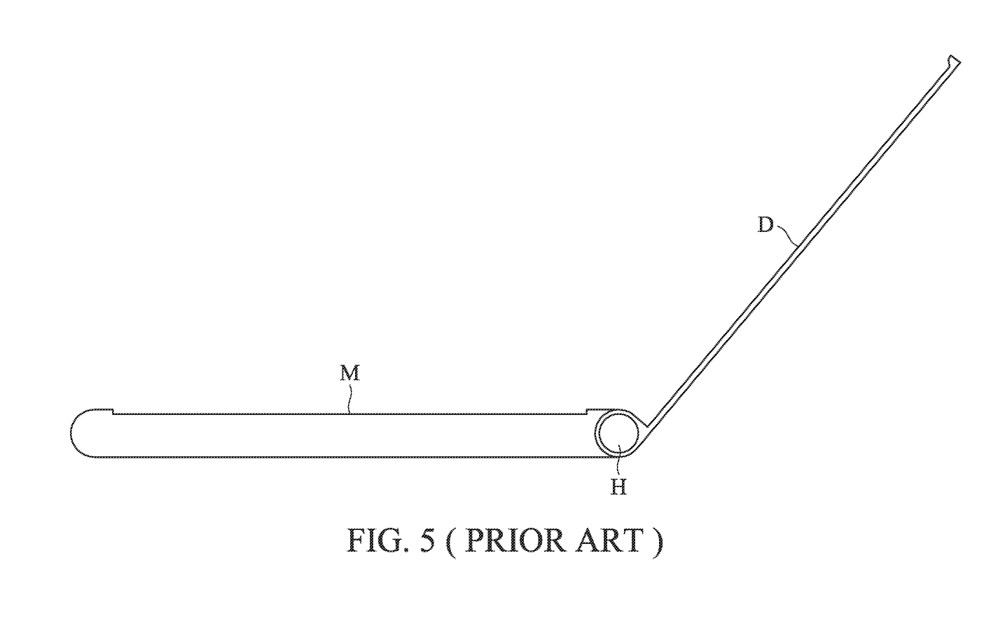

FIG. 1B is a schematic diagram representing a first hinge disposed in a depression according to an embodiment of the invention;

FIG. 1C is a schematic diagram representing a rotary member pivotally connected to a main body and a display module according to an embodiment of the invention;

FIG. 2 is a partial cross-sectional view taken along the line A-A of FIG. 1A according to an embodiment of the invention;

FIG. 3 is a partial cross-sectional view illustrating how a display module rotates relative to the main body to an open position according to an embodiment of the invention;

FIG. 4 is a perspective diagram representing that a display module rotates relative to the main body to an open position according to an embodiment of the invention; and

FIG. 5 shows a conventional portable computer.

### DETAILED DESCRIPTION OF INVENTION

Referring to FIGS. 1A-1C, an embodiment of an electronic device includes a main body 10, a display module 20, a rotary member 30, and a slider 40. The rotary member 30 and the slider 40 are disposed on the same side of the electronic device. As shown in FIG. 1B, a depression 11 is formed on the main body 10. A first hinge 50 is disposed in the depression 11 and pivotally connected to the main body 10, the display module 20, and the slider 30. Furthermore, as shown in FIG. 1C, a second hinge 60 is pivotally connected to the rotary member 30 and the slider 40.

In FIGS. 1A-1C, a recess 21 is formed on the display module 20. The position of the recess 21 corresponds to that of the depression 11. When the display module 20 is in a closed position relative to the main body 10, the slider 40 is accommodated in the recess 21.

FIG. 2 is a partial cross-sectional view taken along the line A-A of FIG. 1A. The display module 20 has a display surface 23, a first surface 24, and a first inclined surface 25. The display surface 23 and the first surface 24 are disposed on opposite sides of the display module 20. The slider 40 has a second surface 41 and a second inclined surface 42. When the display module 20 is in the closed position relative to the main body 10, the first surface 24 is substantially aligned with the second surface 41, and the first inclined surface 25 is adjacent to the second inclined surface 42.

In this embodiment, a first torsion spring (not shown) may be provided and surrounds the first hinge 50, and both ends of the first torsion spring may connect to the main body 10 and the rotary member 30 respectively. Similarly, a second torsion spring (not shown) may be provided and surrounds the second hinge 60, and both ends of the second torsion spring may connect to the rotary member 30 and the slider 40 respectively. The first and second torsion springs can provide a clockwise spring force to the rotary member 30 and the slider 40 respectively. Therefore, the slider 40 can be stably received in the recess 21 (as shown in FIG. 1A).

Referring to FIG. 3, when the display module 20 rotates relative to the main body 10 from the closed position to an open position, the first and second torsion springs can still provide the spring force to the rotary member 30 and the slider 40 respectively. Meanwhile, the display module 20 pushes the slider 40 to rotate counterclockwise (a first direction) relative to the rotary member 30, and the rotary member 30 rotates clockwise (a second direction) relative to the display module 20. Thus, the second inclined surface 42 slides along the first inclined surface 25, and the slider 40 protrudes from the first surface 24 of the display module 20.

In another embodiment of the invention, the first torsion spring can be replaced by a gear mechanism which connects the display module 20 and the rotary member 30. When the display module 20 rotates relative to the main body 10, the rotary member 30 can rotate relative to the display module 20 by the gear mechanism.

FIG. 4 is a perspective diagram illustrating how a display module 20 rotates relative to the main body 10 to an open position, wherein the slider 40 protrudes from the first surface 24. The rotary member 30 and the slider 40 can remain in contact with the surface of the display module 20 by the spring force from the first and second torsion springs. Thus, the rear side 12 of the main body 10 can be exposed with heat dissipation holes, power sockets, or USB sockets disposed thereon.

When the display module 20 rotates relative to the main body 10 from the open position (FIG. 4) to the closed position (FIG. 1A), the first inclined surface 25 of the display module 20 and the second inclined surface 42 of the slider 40 slide relative to each other because of the spring force applied to the slider 40, which is provided by the second torsion spring. Therefore, the slider 40 can smoothly slide back to the recess 21, and interference between the slider 40 and the display module 20 can be avoided.

Because the first hinge 50 is disposed in the depression 11 of the electronic device of the invention, the size and weight of the electronic device can be reduced for easy carrying and storage. As the slider 40 is accommodated in the recess 21 of the display module 20 when the display module 20 is in the closed position relative to the main body 10, the electronic device can achieve an integrated appearance. Furthermore, as the rotary member 30 and the slider 40 can rotate and slide relative to the display module 20 when the display module 20 rotates relative to the main body 10 to the open position, the rear side 12 of the main body 12 can be exposed to external space, and the connectors can also be exposed to the rear side 12.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An electronic device, comprising:
a main body;
a display module, having a recess and a first surface connected to the recess;
a rotary member;
a slider;
a first hinge, disposed on a rear side of the main body, and pivotally connected to the display module and the rotary member; and
a second hinge, pivotally connected to the slider and the rotary member, wherein when the display module is in a closed position relative to the main body, the slider is accommodated in the recess, and when the display module rotates relative to the main body from the closed position to an open position, the display module pushes the slider to rotate relative to the rotary member, the rotary member rotates relative to the display module, and the slider protrudes from the first surface to prevent the rear side from being covered by the rotary member.

2. The electronic device as claimed in claim 1, wherein the main body includes a depression with the first hinge disposed therein.

3. The electronic device as claimed in claim 1, wherein the display module has a display surface, and the display surface and the first surface disposed on opposite sides of the display module, wherein the slider has a second surface, and when the display module is in a closed position relative to the main body, the first surface is aligned with the second surface.

4. The electronic device as claimed in claim 1, wherein the electronic device further comprises a first torsion spring with the first hinge disposed therein, and the first torsion spring connects to the main body and the rotary member.

5. The electronic device as claimed in claim 1, wherein the electronic device further comprises a second torsion spring with the second hinge disposed therein, and the second torsion spring connects to the rotary member and the slider.

6. The electronic device as claimed in claim 1, wherein the electronic device further comprises a gear mechanism connecting the display module with the rotary member, and when the display module rotates relative to the main body from the closed position to the open position, the rotary member is rotated relative to the display module by the gear mechanism.

7. The electronic device as claimed in claim 1, wherein the display module further has a first inclined surface, and the slider has a second inclined surface, wherein when the display module is in the closed position relative to the main body, the first inclined surface is adjacent to the second inclined surface.

8. The electronic device as claimed in claim 1, wherein when the display module rotates relative to the main body from the closed position to the open position, the display module pushes the slider to rotate relative to the rotary member, and the rotary member rotates toward the display module.

9. The electronic device as claimed in claim 1, wherein when the display module rotates relative to the main body from the closed position to the open position, the display module pushes the slider to rotate along a first direction relative to the rotary member, and the rotary member rotates along a second direction relative to the display module, wherein the first direction is opposite to the second direction.

10. The electronic device as claimed in claim 1, wherein when the display module rotates relative to the main body from the closed position to the open position, the second hinge is situated in the recess.
